(19) United States
(12) Patent Application Publication
(10) Pub. No.: US 2023/0044423 A1
(43) Pub. Date: Feb. 9, 2023

(54) PHONONIC MATERIAL AND METHOD FOR PRODUCING SAME

(71) Applicant: Nobuyuki Zen, Ibaraki (JP)

(72) Inventor: Nobuyuki Zen, Ibaraki (JP)

(21) Appl. No.: 17/789,064

(22) PCT Filed: Dec. 23, 2020
(86) PCT No.: PCT/JP2020/048218

§ 371 Date: Jun. 24, 2022

(30) Foreign Application Priority Data
Dec. 28, 2019 (JP) 2019-239997

(51) Int. Cl. H01L 39/24; H01L 39/12

(52) U.S. Cl. CPC H01L 39/2419; H01L 39/128

(57) ABSTRACT

[Problem] To provide a phononic material that exhibits an electrical resistance characteristic less than or equal to 0Ω, a precursor of the same, and a method for producing these. [Solution] A phononic material 1 has a periodic structure body 2′ in which structures 3 are periodically and regularly disposed in a constituent 2. The periodic structure body 2′ exhibits an electrical resistance characteristic less than or equal to 0Ω, and has a temperature region that exhibits the electrical resistance characteristic in a temperature range exceeding a superconducting transition temperature when the constituent 2 has the superconducting transition temperature. A method for producing a precursor of the phononic material 1 includes a pretreatment process to obtain the precursor by carrying out a heat treatment to warm the periodic structure body after cooling the periodic structure body in a state of applying a unidirectional current to the periodic structure body 2′.

### TECHNICAL FIELD

The present invention relates to a phononic material to which phonon engineering is applied, and a method for producing the same.

### BACKGROUND ART

Research on phonon engineering is underway to manipulate phonons propagating in a constituent artificially by periodically and regularly disposing arbitrary structures in the constituent.

For example, the present inventor succeeded in lowering the thermal conductivity of an insulator by about one order by applying phonon engineering to the insulator (see Non-Patent Document 1).

Further, there is a suggestion to try to improve the sensitivity of an infrared sensor by applying phonon engineering to beams, each composed of an insulator or a semiconductor and connected to an infrared receiver, to lower the thermal conductivity of the beam (see Patent Document 1).

In either case, the propagation of heat in the constituent is described by the propagation of phonons (lattice vibration). In general, although a phonon dispersion relation is defined by the type of constituent and the thermal conductivity is defined by an inherent phonon dispersion relation of the constituent, the inherent thermal conductivity of the insulator can be lowered by applying phonon engineering to the insulator to manipulate the phonon dispersion relation artificially.

Thus, attention is focused on phonon engineering to control the thermal conductivity artificially in the future, but further progress is required for technology related to superconductivity.

For example, research is being conducted to try to improve superconducting transition temperature using the structural change of a cage-shaped structure body, but the phonon dispersion relation is not affected because a structure having about an atomic-scale size (the order of picometers to the order of a few nanometers) is targeted as the cage-shaped structure.

In addition, it is found that the superconducting transition temperature of the cage-shaped structure is not improved, or rather that the inherent superconducting properties of the constituent of the cage-shaped structure body are impaired (see Non-Patent Documents 2 and 3).

In the meantime, the present inventor reports the transition of a phonon-engineered metal plate to an insulator by repeating the heat treatment of cooling and warming of the metal plate (phononic material) (see Non-Patent Document 4).

This indicates such a phenomenon that, when a periodic structure body in which structures are periodically and regularly disposed in a constituent is cooled, the material order of the constituent before cooling changes to form a new material order, and that this new material order is maintained after warming to give new physical properties that the constituent does not have by nature. Metals and semiconductors are different from insulators in that charged carriers such as electrons and holes exist in the constituent. Since this phenomenon is not confirmed even when the heat treatment is repeatedly carried out on a constituent to which the phonon engineering is not applied, the phenomenon is understood to be a phenomenon that occurs only in the constituent that constructs the periodic structure body, which is based on the interaction of phonons (lattice vibration) in the constituent that constructs the periodic structure body with carriers in the constituent when cooling and warming.

This means that the material order that the constituent cannot have by nature can be exhibited artificially through phonon control based on artificial settings of the structures disposed in the periodic structure body.

### PRIOR ART DOCUMENTS

### Patent Document

Patent Document 1: Japanese Patent Application Publication No. 2017-223644

### Non-Patent Documents

Non-Patent Document 1: N. Zen et al., Nature Commun. 5:3435 (2014)
Non-Patent Document 2: J. Tang et al., Phys. Rev. Lett. 105, 176402 (2010)
Non-Patent Document 3: R. Ang et al., Nature Commun. 6:6091 (2015)
Non-Patent Document 4: N. Zen, AIP Adv. 9, 095023 (2019)
Non-Patent Document 5: J. Bardeen et al., Phys. Rev. 106, 162 (1957)

### SUMMARY OF THE INVENTION

### Problems to be Solved by the Invention

The present invention is to solve the various conventional problems and achieve the following object, that is, an object to provide a phononic material that exhibits an electrical resistance characteristic less than or equal to 0Ω, a precursor of the same, and a method for producing these.

A mechanism for the transition of a metal to a superconductor is described by BCS theory in which inter-electron interaction mediated by a phonon is written (see Non-Patent Document 5).

Although the present inventor aimed to develop properties as a superconductor artificially by controlling phonons in the phononic material based on the BCS theory, it resulted in the transition of the metal plate to the insulator as described above (see Non-Patent Document 4).

An Anderson localization phenomenon is observed in the insulator, and this suggests that carriers receive a spatial disturbance and cannot move.

Although the phenomenon in which the transition of the metal plate to the insulator is made is an unusual phenomenon in itself, the present inventor hypothesized that a special carrier movement characteristic can be developed in the interaction with phonons by performing the heat treatment by cooling and warming without giving any spatial disturbance to the carriers in the constituent, and after a further examination along with trial and effort, the present inventor gained such a finding that the periodic structure body exhibiting the electrical resistance characteristic less than or equal to 0Ω can be obtained when a precursor is produced under certain conditions.

### Means for Solving the Problems

The present invention is based on the finding, and means for solving the problems are as follows, namely:

<1> A phononic material including a periodic structure body in which structures are periodically and regularly disposed in a constituent containing elements having d orbital, wherein the periodic structure body exhibits an electrical resistance characteristic less than or equal to 0Ω, and has a temperature region that exhibits the electrical resistance characteristic in a temperature range exceeding a superconducting transition temperature when the constituent has the superconducting transition temperature.

<2> The phononic material described in <1>, wherein the periodic structure body exhibits an electrical resistance characteristic of a negative value.

<3> The phononic material described in <1> or <2>, wherein the constituent contains a transition metal element.

<4> The phononic material described in any one of <1> to <3>, wherein the periodic structure body is formed in a layer state, and the structures are through holes.

<5> The phononic material described in <4>, wherein the opening diameter of each through hole is 1 nm to 10 mm.

<6> The phononic material described in <4> or <5>, wherein an interval between adjacent two through holes is 1 nm to 0.1 mm.

<7> The phononic material described in any one of <4> to <6>, wherein the thickness of the periodic structure body formed in the layer state is 0.1 nm to 0.01 mm.

<8> A phononic material including a periodic structure body in which structures are periodically and regularly disposed in a constituent containing elements having d orbital, wherein the periodic structure body does not develop a bifurcation phenomenon as a phenomenon in which, when a cooling resistance temperature characteristic of the periodic structure body in a cooling process of continuous heat cycles to raise temperature after cooling the periodic structure body is compared with a warming resistance temperature characteristic of the periodic structure body in a warming process, the warming resistance temperature characteristic bifurcates from the cooling resistance temperature characteristic to exhibit a high electrical resistance value at a common temperature.

<9> A method for producing the phononic material described in <8>, including a pretreatment process to obtain a precursor as the periodic structure body that does not develop the bifurcation phenomenon by carrying out a heat treatment to warm the periodic structure body up to a temperature exceeding a bifurcation temperature after cooling the periodic structure body up to a temperature lower than the bifurcation temperature in a state of applying a unidirectional current to the periodic structure body until the bifurcation phenomenon disappears, where the bifurcation temperature is a temperature at which the cooling resistance temperature characteristic and the warming resistance temperature characteristic bifurcate each other in the bifurcation phenomenon.

<10> A method for producing the phononic material described in any one of <1> to <7>, including a cooling-warming process to carry out a heat treatment on a precursor as the periodic structure body that does not develop a bifurcation phenomenon up to a temperature exceeding a bifurcation temperature after cooling the precursor up to a temperature lower than the bifurcation temperature until the warmed precursor exhibits an electrical resistance value of 0Ω or less, where the bifurcation phenomenon is a phenomenon in which, when a cooling resistance temperature characteristic of the periodic structure body in a cooling process of continuous heat cycles to raise temperature after cooling the periodic structure body is compared with a warming resistance temperature characteristic of the periodic structure body in a warming process, the warming resistance temperature characteristic bifurcates from the cooling resistance temperature characteristic to exhibit a high electrical resistance value at a common temperature, and the bifurcation temperature is a temperature at which the cooling resistance temperature characteristic and the warming resistance temperature characteristic bifurcate each other in the bifurcation phenomenon.

### Advantageous Effect of the Invention

According to the present invention, the various problems in conventional technology can be solved, and a phononic material that exhibits an electrical resistance characteristic less than or equal to 0Ω, a precursor of the same, and a method for producing these can be provided.

### BRIEF DESCRIPTION OF THE DRAWINGS

FIG. 1(a) is an explanatory drawing illustrating the top surface of a phononic material according to one embodiment of the present invention.

FIG. 1(b) is an explanatory drawing illustrating an A-A′ line section in FIG. 1(a).

FIG. 2(a) is a diagram (1) illustrating a modification of structures.

FIG. 2(b) is a diagram (2) illustrating another modification of the structures.

FIG. 2(c) is a diagram (3) illustrating still another modification of the structures.

FIG. 2(d) is a diagram (4) illustrating yet another modification of the structures.

FIG. 3(a) is an explanatory drawing illustrating a configuration example of a one-dimensional phononic material.

FIG. 3(b) is an explanatory drawing (1) illustrating a configuration example of a three-dimensional phononic material.

FIG. 3(c) is an explanatory drawing (2) illustrating a configuration example of the three-dimensional phononic material.

FIG. 4 is an explanatory drawing illustrating the state of a niobium layer as viewed from the top.

FIG. 5 is an explanatory drawing illustrating each of rectangular block regions when the niobium layer is viewed from above.

FIG. 6(a) is a graph for describing the status of carrying out a pretreatment process on a phononic material according to Example 1 and the transition status of electrical resistance values.

FIG. 6(b) is a partially enlarged graph in which a range of 20 K to 60 K in FIG. 6(a) is enlarged.

FIG. 6(c) is a partially enlarged graph in the first cycle.

FIG. 6(d) is a partially enlarged graph in the sixth cycle.

FIG. 6(e) is a graph (1) illustrating the status of carrying out a cooling-warming process on the phononic material according to Example 1 and the transition status of electrical resistance values.

FIG. 6(f) is a graph (2) illustrating the status of carrying out the cooling-warming process on the phononic material according to Example 1 and the transition status of electrical resistance values.

FIG. 6(g) is a graph (3) illustrating the status of carrying out the cooling-warming process on the phononic material according to Example 1 and the transition status of electrical resistance values.

FIG. 6(h) is a graph (4) illustrating the status of carrying out the cooling-warming process on the phononic material according to Example 1 and the transition status of electrical resistance values.

FIG. 7 is a graph illustrating characteristic changes of the periodic structure body in a heat treatment (the pretreatment process) from the first cycle to the fifth cycle.

FIG. 8 is a graph in which the cycle number z′ is plotted on the horizontal axis and the 300 K resistance value R_{300K} is plotted on the vertical axis for the periodic structure body in the heat treatment from the first cycle to the fifth cycle.

FIG. 9 is a diagram schematically illustrating a transition state of the periodic structure body to a superconducting precursor in the pretreatment process.

FIG. 10(a) is a graph illustrating the status of carrying out a superconductivity recovery process on a phononic material according to Example 2 and the transition status of electrical resistance values.

FIG. 10(b) is a partially enlarged graph in which a range of 20 K to 60 K in FIG. 10(a) is enlarged.

FIG. 11 is a graph illustrating the results of voltage-current characteristic measurement made on the phononic material according to Example 2.

FIG. 12(a) is a graph illustrating the results of a voltage-current characteristic measurement when a direct current is applied to the phononic material according to Example 2.

FIG. 12(b) is a graph illustrating the results of a voltage-current characteristic measurement when the direct current is applied to the phononic material according to Example 2 after applying a current exceeding a critical current value.

FIG. 13(a) is a graph for describing the status of carrying out the pretreatment process and the cooling-warming process on a phononic material according to Example 3 and the transition status of electrical resistance values.

FIG. 13(b) is a partially enlarged graph in which a range of 20 K to 60 K in FIG. 13(a) is enlarged.

FIG. 13(c) is a graph (1) illustrating the status of carrying out the cooling-warming process on the phononic material according to Example 3 and the transition status of electrical resistance values.

FIG. 13(d) is a graph (2) illustrating the status of carrying out the cooling-warming process on the phononic material according to Example 3 and the transition status of electrical resistance values.

FIG. 13(e) is a graph (3) illustrating the status of carrying out the cooling-warming process on the phononic material according to Example 3 and the transition status of electrical resistance values.

FIG. 13(f) is a partially enlarged graph in which a range of 25 K to 100 K in FIG. 13(e) is enlarged.

FIG. 14 is a graph for the periodic structure body in the heat treatment of the first to third cycles, in which the 300 K resistance value R_{300K} is plotted on the vertical axis and z″ is plotted on the horizontal axis in such a manner that R_{300K} immediately before the heat treatment of the first cycle is carried out corresponds to z″=0, R_{300K} in the first cycle corresponds to z″=2, R_{300K} in the second cycle corresponds to z″=4, and R_{300K} in the third cycle corresponds to z″=5, respectively.

FIG. 15 is a graph illustrating resistance temperature characteristics of the periodic structure body in the phononic material according to Example 3.

### MODE FOR CARRYING OUT THE INVENTION

(Phononic Materials)

A first phononic material of the present invention has a periodic structure body that exhibits an electrical resistance characteristic less than or equal to 0Ω, and to have a temperature region indicative of the electrical resistance characteristic in a temperature range exceeding a superconducting transition temperature when a constituent that constructs the periodic structure body has the superconducting transition temperature.

Here, as a method for measuring an electrical resistance value, for example, there is a known four-terminal method.

Further, as a method for checking whether or not the constituent has the superconducting transition temperature, for example, there are a method for referring to known data, and a known method for cooling the constituent to check the superconducting transition temperature.

Further, a second phononic material of the present invention is a precursor of the first phononic material, which has the periodic structure body that does not develop a bifurcation phenomenon as a phenomenon in which, when a cooling resistance temperature characteristic of the periodic structure body in a cooling process of continuous heat cycles to raise temperature after cooling the periodic structure body is compared with a warming resistance temperature characteristic of the periodic structure body in a warming process, the warming resistance temperature characteristic bifurcates from the cooling resistance temperature characteristic to exhibit a high electrical resistance value at a common temperature.

As a method for measuring the bifurcation phenomenon, there is a method for measuring the bifurcation phenomenon to be described later in a “pretreatment process” related to the production method.

Although both the first and second phononic materials have the common periodic structure body, the first phononic material exhibits properties different from those of the second phononic material through a production process in which the second phononic material is used as the precursor.

In this specification, the structure of the periodic structure body and various properties given to the periodic structure body will first be described, and a method for producing each of the first and second phononic materials to give these properties to the periodic structure body will next be described.

Since the first phononic material has a property similar to that of a superconductor in terms of the electrical resistance value, the periodic structure body in the first phononic material may be called a “superconductor” below for the purpose of distinguishing from the periodic structure body without this property. Further, the periodic structure body in the second phononic material may be called a “superconducting precursor.”

<Periodic Structure Body>

The periodic structure body is so constructed that structures are periodically and regularly disposed in a constituent containing elements having d orbital.

The periodic structure body thus constructed is also called a phononic crystal in contrast to a normal crystal exhibiting a state in which atoms and molecules are periodically and regularly disposed in a material.

In the phononic crystal, the arrangement of the structures can be set artificially, and the setting method draws attention to phonon engineering.

In such a periodic structure body (phononic crystal), a property that the phonon group velocity and energy density become smaller than those of a constituent in a bulk state without any structures.

The degree of this property changes depending on how to arrange the structures. In other words, the phonon group velocity and energy density can be changed in the periodic structure body depending on the phonon engineering to be applied. These phonon group velocity and energy density have such a relation that when one of them becomes smaller, the other becomes smaller, and when one of them becomes larger, the other becomes larger.

The periodic structure body is not particularly limited. However, when paying attention to the phonon group velocity of the constituent in the periodic structure body, it is preferred that the phonon group velocity of the constituent in the periodic structure body should be less than or equal to ½ of that of the constituent in the bulk state because it is easier to control the behavior of electrons and holes in the constituent as the phonon group velocity and energy density are smaller.

The constituent is not particularly limited as long as it is a substance containing elements having d orbital, and it can be selected from among known metal materials and semiconductor materials as appropriate according to the purpose. In other words, in the first and second phononic materials, physical properties different from the physical properties intrinsic to the constituent are acquired by using a phenomenon in which phonons in the constituent interact with electrons in the constituent during heat treatment by cooling and warming, but the phenomenon can occur in any substance. This is because phonons always exit as long as it is a substance. On the other hand, the constituent must be a substance containing elements having d orbital. This is because properties as the superconductor and the superconducting precursor can be obtained by interaction between electrons in d orbital and phonons.

Above all, as the constituent, a substance containing a transition metal element (an element belonging to group 3 to group 12) is preferred, and a substance constructed as a single substance of the transition metal element is particularly preferred.

The transition metal element is not particularly limited, but an element with vacancy in d orbital is preferred, and when the constituent contains the transition metal element without vacancy in d orbital, it is preferred to be constructed as an alloy or a semiconductor compound.

Further, it is preferred to be selected from superconducting substances that exhibit the properties of a superconductor in the bulk state. In other words, use of a substance originally having the properties of the superconductor makes it easier to build a new material order to give properties as the superconductor to the periodic structure body.

The structures are not particularly limited, and can be selected according to the purpose, such as structures applied to a known phononic crystal.

Above all, when the periodic structure body is formed in a layer state, it is preferred that the structures should be through holes pierced in a thickness direction of the layer. When the structures are formed as the through holes, the periodic structure body can be produced by known lithography, and this makes it easier to stably obtain a group of the structures regularly disposed in the periodic structure body. Further, when the structures are formed as the through holes, a filling substance formed of a different material from the constituent may be filled in the through holes to adjust the phonon group velocity and energy density.

Note that a case where the periodic structure body is constructed by repeatedly disposing unit structure bodies, each of which is constructed of plural structures with different shapes, is included as the periodic structure body in addition to the case where the periodic structure body is constructed by repeatedly disposing structures of the same shape.

The period to form the structures in the periodic structure body, that is, the interval between adjacent two of the structures may be any period in a phonon wavelength scale (for example, in a scale from the order of nanometers to the order of millimeters (1 nm to 10 mm)), and when the period is such a period, the phonon group velocity and energy density of the constituent in the periodic structure body become smaller than those of the constituent in the bulk state.

Further, the size of each of the structures may also be any size in the phonon wavelength scale (for example, in the scale from the order of nanometers to the order of millimeters (1 nm to 10 mm)), and when the size is such a size, the phonon group velocity and energy density of the constituent in the periodic structure body become smaller than those of the constituent in the bulk state.

Note that the size of each of the structures corresponds to the maximum diameter of the structure. For example, in the case of the through hole, when the opening diameter is larger than the depth thereof, the size corresponds to the opening diameter, and when the width has a shape larger than the length in the opening diameter, the size corresponds to the length.

Further, in such an aspect that the periodic structure body is formed in a layer state and the structures are the through holes pierced in the thickness direction of the layer as described as a preferred form of the periodic structure body, when the conditions below are further met, it is further easier to build a new material order to give properties as a superconductor to the periodic structure body.

In other words, it is preferred that the opening diameter of each of the through holes should be 1 nm to 10 mm, and it is more preferred that it should be 10 nm to 1 mm.

Further, it is preferred that the interval between adjacent two through holes should be 1 nm to 0.1 mm, and it is more preferred that it should be 10 nm to 0.01 mm.

Further, it is preferred that the layer thickness of the periodic structure body should be 0.1 nm to 0.01 mm, and it is more preferred that it should be 1 nm to 0.001 mm.

Note that the periodic structure body is not particularly limited, which may be produced by a known method for producing a phononic crystal, or a known phononic crystal produced in advance may be used.

### Embodiment

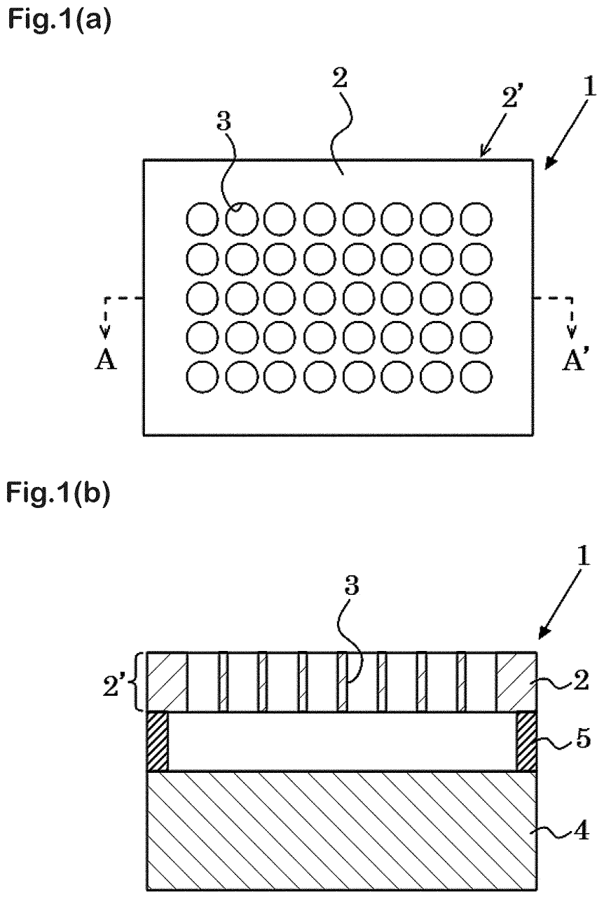

A phononic material according to an embodiment of the present invention will be described with reference to the accompanying drawings. FIG. 1(a) is an explanatory drawing illustrating the top surface of a phononic material according to one embodiment of the present invention, and FIG. 1(b) is an explanatory drawing illustrating an A-A′ line section in FIG. 1(a).

As illustrated in FIG. 1(a) and FIG. 1(b), a phononic material 1 has a periodic structure body 2′ in which cylindrical through holes as structures 3 are periodically and regularly disposed in a constituent 2.

The periodic structure body 2′ is placed on a substrate 4 through spacers 5. The spacers 5 are placed to support the periodic structure body 2′ at the outer peripheral positions of a region in which the structures 3 are formed. The substrate 4 and the spacers 5 are provided to measure property changes of the periodic structure body 2′ during cooling and warming, and a region on the side of the bottom of the periodic structure body 2′ (the surface on the side of the substrate 4) in which the structures 3 are formed is made hollow to be able to measure property changes of the periodic structure body 2′ without being affected by phonons existing in this region.

Further, the substrate 4 is made of a material such as Si used in general microfabrication from the point of view of producing such a structure. Further, from the point of view of performing such a measurement, the spacers 5 are made of an electrically insulating material such as SiO₂.

Note that the substrate 4 and the spacers 5 can be removed before or after the superconducting properties are exhibited in the periodic structure body 2′ to make the periodic structure body 2′ itself as a phononic material.

The periodic structure body 2′ illustrated in FIG. 1(a) and FIG. 1(b) is an example for description, and the settings of each of the structures 3, the number of formations, the arrangement thereof, and the like can be selected as appropriate according to the purpose.

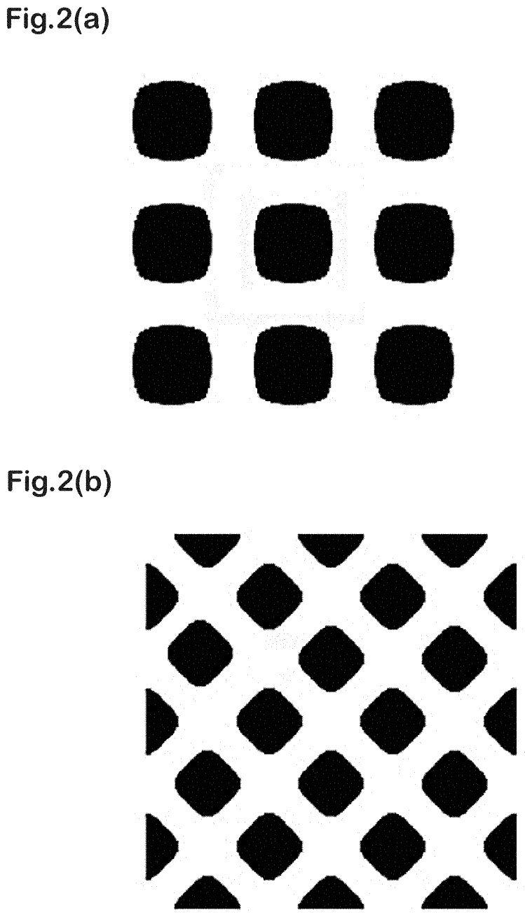

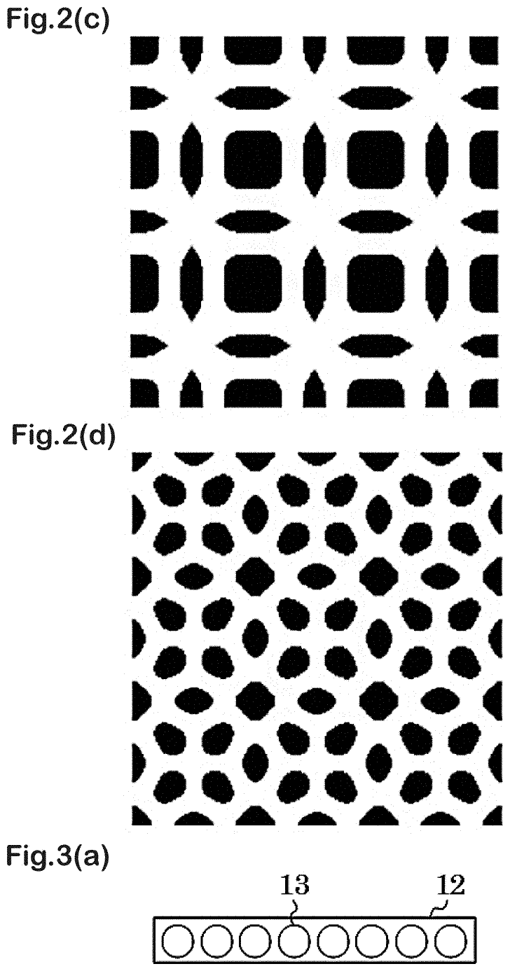

Modifications of the structures 3 are illustrated in FIG. 2(a) to FIG. 2(d). Note that FIG. 2(a) to FIG. 2(d) are diagrams (1) to (4) illustrating the modifications of the structures, respectively.

In the example illustrated in FIG. 2(a), the structures are formed as substantially square columnar structures. Further, in the example illustrated in FIG. 2(b), the regularity of disposing the through holes illustrated in FIG. 2(a) is changed.

Even in the periodic structure body having these structures, such properties that the phonon group velocity and energy density become smaller than those of the constituent in the bulk state can be obtained as the phononic crystal.

In FIG. 2(c) and FIG. 2(d), examples in which the periodic structure body is constructed by repeatedly disposing unit structures, each of which is constructed of plural structures with different shapes, are illustrated.

Even in the periodic structure body in which the unit structures are formed as the structures, such properties that the phonon group velocity and energy density become smaller than those of the constituent in the bulk state can be obtained as the phononic crystal.

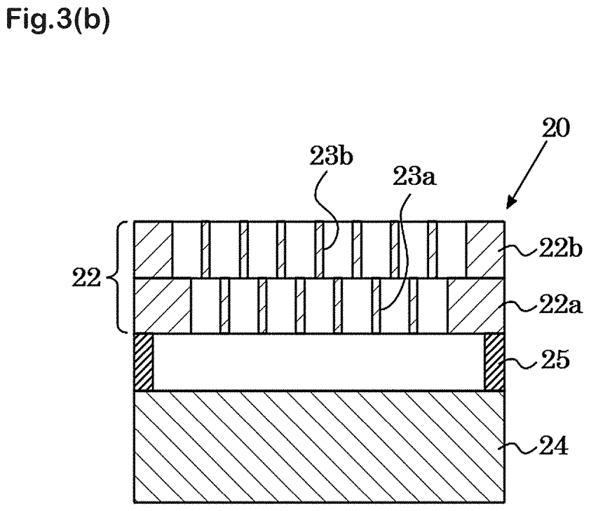

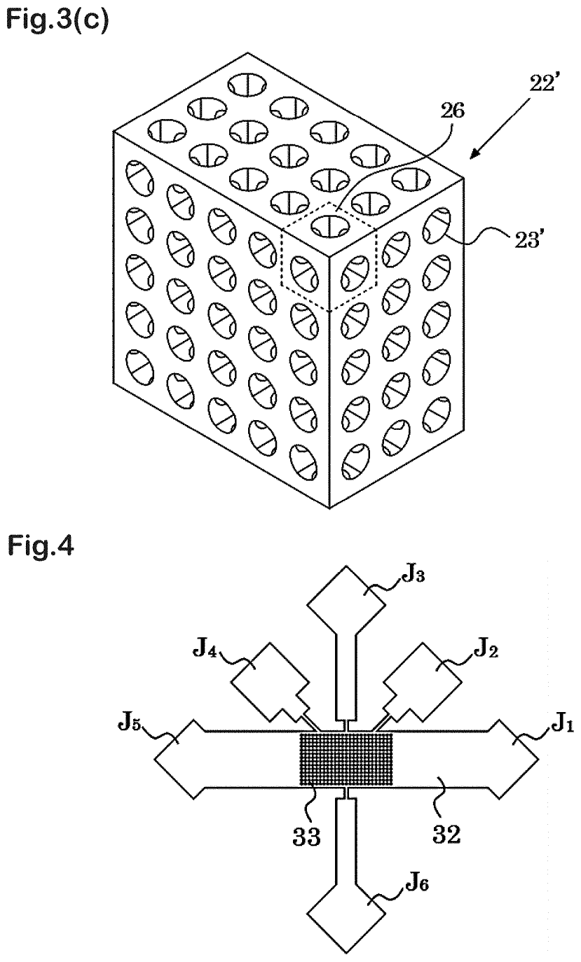

Further, in the periodic structure body 2′ illustrated in FIG. 1(a) and FIG. 1(b), the arrangement of the structures 3 is a two-dimensional arrangement with periodicity in the width and length directions of the periodic structure body 2′ especially as illustrated in the top view of FIG. 1(a), but the arrangement may also be a one-dimensional arrangement or a three-dimensional arrangement (see FIG. 3(a) to FIG. 3(c)). Note that FIG. 3(a) is an explanatory drawing illustrating a configuration example of a one-dimensional phononic material, FIG. 3(b) is an explanatory drawing (1) illustrating a configuration example of a three-dimensional phononic material, and FIG. 3(c) is an explanatory drawing (2) illustrating a configuration example of a three-dimensional phononic material.

In other words, in a periodic structure body 12 illustrated in FIG. 3(a), the arrangement of structures 13 is a one-dimensional arrangement with periodicity in the length direction of the periodic structure body 12.

Further, in a periodic structure body 22 illustrated in FIG. 3(b), which is formed in a similar manner to the periodic structure body 2′ illustrated in FIG. 1(a) and FIG. 1(b), the arrangement of structures 23a and 23b is a tree-dimensional arrangement with periodicity in the thickness direction in addition to the width and length directions of the periodic structure body 22 by laminating, in the thickness direction of the periodic structure body 22, a layer of a constituent 22a with the structures 23a formed therein and a layer of a constituent 22b with the structures 23b formed therein. Note that reference numeral 24 in FIG. 3(b) indicates a substrate and reference numeral 25 indicates spacers.

Further, in a periodic structure body 22′ illustrated in FIG. 3(c), unit structures each of which is a cubic block region 26 with circular holes as structures 23′ formed on respective sides are constructed to have three-dimensional periodic arrays in which plural unit structures are combined in the height direction and the width and length directions of the periodic structure body 22′. Note that the periodic structure body 22′ can be produced by a known 3D printer or the like.

The phononic material having each of these periodic structure bodies is given properties as the first phononic material exhibiting the properties as the superconductor, and properties as the second phononic material exhibiting the properties as the superconducting precursor depending on the production stage of a production method to be described below.

(Production Method of Phononic Material)

A production method of a first phononic material of the present invention is a production method of the second phononic material as a precursor of the first phononic material that exhibits properties as the superconductor, which includes a pretreatment process.

Further, a production method of a second phononic material of the present invention is a production method of the first phononic material having the second phononic material as a precursor, which includes a cooling-warming process.

<Pretreatment Process>

The pretreatment process is a process to obtain a precursor (superconducting precursor) as the periodic structure body that does not develop a bifurcation phenomenon by performing a heat treatment to warm the periodic structure body up to a temperature exceeding a bifurcation temperature after cooling the periodic structure body up to a temperature lower than the bifurcation temperature in a state of applying a unidirectional current to the periodic structure body until the bifurcation phenomenon disappears, where the bifurcation phenomenon is a phenomenon in which, when a cooling resistance temperature characteristic of the periodic structure body in a cooling process of continuous heat cycles to raise temperature after cooling the periodic structure body is compared with a warming resistance temperature characteristic of the periodic structure body in a warming process, the warming resistance temperature characteristic bifurcates from the cooling resistance temperature characteristic to exhibit a high electrical resistance value at a common temperature, and the bifurcation temperature is a temperature at which the cooling resistance temperature characteristic and the warming resistance temperature characteristic bifurcate each other in the bifurcation phenomenon.

In the periodic structure body, the bifurcation phenomenon in which, when the cooling resistance temperature characteristic of the periodic structure body in the cooling process of continuous heat cycles to raise temperature after cooling the periodic structure body is compared with the warming resistance temperature characteristic of the periodic structure body in the warming process, the warming resistance temperature characteristic bifurcates from the cooling resistance temperature characteristic to exhibit a high electrical resistance value at a common temperature is developed.

In the periodic structure body in the state of developing this phenomenon, since electrons remain itinerant in the constituent and the interaction between electrons is not strengthened to the extent that the electrons are localized, it is hard to give properties as the superconductor to the periodic structure body.

Therefore, the pretreatment process is carried out to make the electrons in the constituent localized strongly until the electrons in the constituent cannot itinerate in order to make the bifurcation phenomenon not to be developed.

In other words, the electrons in the constituent are localized strongly in d orbital, and the superconducting precursor to give the properties as the superconductor to the periodic structure body is formed in the cooling-warming process as the next process.

Here, a state of localizing the electrons in d orbital during the pretreatment process can be observed as the Friedel sum rule (see Reference Document 1, pp. 50-57, below). In general, the Friedel sum rule describes such a phenomenon that, when a different transition metal element is mixed as an impurity in a maternal transition metal, resistance R rises to satisfy the relationship of R∞ sin²(z×π/10) according to a difference z in valence. Since the number of d orbitals is five and two spin-up and spin-down electrons can go into each orbital in total, 10 electrons can be localized to occupy the d orbitals at the maximum.

Reference Document 1: Postgraduate Condensed Matter Physics II, Strongly Correlated Electron System, supervised by Muneyuki Date, Kodansha Ltd. (1997)

In the periodic structure body, the electrons of the constituent are localized one by one in d orbital each time the heat treatment is repeated in the pretreatment process as if it were growing as a material different from the constituent of the base material. The state is observed as a resistance increase to satisfy the relationship of R∞ sin²(z′×π/10) when the resistance is denoted by R and the number of heat treatment processes is denoted by z′.

For example, when the constituent is niobium, the d orbitals are occupied by four to five electrons under normal conditions, and there are five to six vacant spaces. Therefore, in the periodic structure body using niobium as the constituent, the pretreatment process containing five to six times of the heat treatment is carried out to localize the electrons in the constituent in a manner to occupy the d orbitals completely. Note that when two electrons are located in each d orbital, the pretreatment process is carried out about three times (R∞ sin²(2z′×π/10)).

Here, when the electrons supplied into the constituent are not spatially uniform, Anderson localization to localize the electrons due to the spatial disturbance becomes apparent. In other words, in this case, the transition of the periodic structure body to the insulator is made at once without observing such a state that one or two electrons occupy each d orbital (see Non-Patent Document 4). It is important for the superconducting precursor to localize the electrons in the constituent in order to occupy the d orbitals completely, and the Anderson-type insulator cannot realize the superconducting precursor.

In contrast, in the pretreatment process, electrons are supplied into the constituent spatially uniformly by applying the unidirectional current to the periodic structure body. As a specific method, there is a method in which a sample with the periodic structure body formed therein is cut out into a plate shape (one-dimension or two-dimension) or a column shape (three-dimension), and respective ends of the sample as electrodes are connected to a current source to apply current from one end side to the other end side. In other words, the electrons can be supplied into the constituent spatially uniformly as long as the paths of the current flowing through the periodic structure body are restricted in the same direction.

Note that the current applied to the periodic structure body is not particularly limited, which can be either a direct current or a square wave current.

In the periodic structure body that has undergone the pretreatment process, it is inferred from empirical results in examples to be described later that electrons localized in d orbitals in the constituent interact with phonons according to the positional relationship between the structures and the constituent to have such a structure that parts (Mott-insulating parts) that allow metal-Mott insulator transitions (see Reference Document 2 below) and the other parts, that is, parts (conducting parts) in which electrons and holes intrinsic to the constituent can itinerate freely are arranged regularly according to the structure of the periodic structure body.

Reference Document 2: Metal-Insulator Transitions (Second Edition), by Nevill F. Mott, Maruzen Publishing Co., Ltd. (1996)

Although the mechanism to develop high-temperature superconductivity has not been academically settled yet, a high-temperature superconductor typified by YBCO or BSCCO is a three-dimensional periodic structure body in which conductive layers composed of copper oxide and insulating layers are regularly laminated. In this respect, since the periodic structure body after going through the pretreatment process also has the structure that the conducting parts and the Mott-insulating parts are regularly arranged, there is a structural similarity.

On the other hand, there is a difference in lattice constant scale between the high-temperature superconductor and the periodic structure body. The former arrangement interval is in an atomic scale order, which is the order of sub-nanometers. On the other hand, the latter arrangement interval is in a phonon wavelength scale (for example, in a scale from the order of nanometers to the order of millimeters (1 nm to 10 mm)). In the discussion of a crystal structure in Chapter 1 of Introduction to Solid State Physics goes on from the tacit fact that the lattice constant is in the atomic scale, but the discussion of the crystal structure does not depend on the magnitude of the lattice constant as a matter of fact (see Reference Document 3, pp. 1-11, below). This is why the phononic material is also called a phononic crystal. In other words, the superconducting precursor is a macro-scale crystal composed of the conducting parts and the Mott-insulating parts.

In the meantime, the high-temperature superconductor is made originally as a result of a superconducting phase transition by doping carriers such as electrons and holes into a material originally having an antiferromagnetic phase such as the Mott-insulator. The act of increasing the dopant concentration of carriers done there is nothing but an act to increase a quantum mechanical probability t of the carriers to jump from one conductive layer to an adjacent conductive layer across the insulating layer so as to weaken a repulsive interaction U between electrons because it is originally the Mott-insulator. In other words, the properties as a superconductor are developed by giving a good balance between the quantum mechanical probability t and the repulsive interaction U between electrons.

From another point of view, the high-temperature superconductor can be regarded as a collection of tunnel junctions that repeat arrays of conductive layer-insulating layer-conductive layer-insulating layer-conductive layer . . . , and the power storage states of respective tunnel junctions are well balanced by increasing the dopant concentration of carriers to form a superconductor. In fact, the high-temperature superconductor is also called an intrinsic Josephson junction, and a critical current value as a maximum applied current value at which the high-temperature superconductor can preserve the properties as the superconductor can be explained by an Ambegaokar-Baratoff relational expression as an expression to give a critical current value of the Josephson junction (see Reference Document 4 below).

Reference Document 3: Introduction to Solid State Physics (Seventh Edition), by Charles Kittel, Maruzen Publishing Co., Ltd. (1998)

Reference Document 4: R. Kleiner et al., Phys. Rev. B 49, 1327 (1994)

Here, the Ambegaokar-Baratoff relational expression is represented by Equation (1) below, where the critical current value is denoted by Ic, the metallic resistance value is denoted by Rn, the superconducting energy gap in the superconducting state is denoted by A, the temperature is denoted by T, the elementary charge is denoted by e, and the Boltzmann constant is denoted by k_{B}.

$$[ Math . 1 ]$$

$${I}_{C} = \frac{Δ}{2 {eR}_{n}} tanh ( \frac{Δ}{2 {k}_{B} T} ) \qquad ( 1 )$$

When the same idea as the high-temperature superconductor is also introduced into the superconducting precursor, the superconducting precursor can be regarded as a collection of tunnel junctions in which tunnel junctions, each composed of the conducting part-the Mott-insulating part-the conducting part, are regularly disposed. In the cooling-warming process as the next process, when the power storage state of each tunnel junction is well balanced, the intrinsic Josephson junction is formed just like the high-temperature superconductor, and the Ambegaokar-Baratoff relational expression is satisfied to develop the properties as the superconductor.

Although the cooling and warming speed in the pretreatment process is not particularly limited, it is preferred to be 1 K/min or less because it is easy to localize electrons in d orbitals in the constituent. Note that the lower limit of the speed is about 0.01 K/min in terms of efficiency.

The cooling temperature in the pretreatment process is not particularly limited as long as it is a temperature lower than the bifurcation temperature, and the cooling temperature can be set, for example, to a temperature about 20 K lower than the bifurcation temperature.

Further, the warming temperature in the pretreatment process is not particularly limited as long as it is a temperature exceeding the bifurcation temperature, and the warming temperature can be set, for example, to a temperature about 40 K higher than the bifurcation temperature.

Further, when the pretreatment process is performed in a wide temperature range, a temperature of 2 K or lower (lower limit: about 10 mK) may be set as the cooling temperature (lowest temperature), and a temperature of 300 K or higher (upper limit: about 400 K) may be set as the warming temperature (highest temperature).

Equipment to carry out the pretreatment process is not particularly limited, and a known refrigerant Dewar or refrigerator can be used, for example.

Note that, when the bifurcation temperature is different between heat treatment cycles of cooling and warming and it is confirmed as a wide temperature zone, cooling is performed at a temperature lower than this temperature zone and warming is performed at a temperature higher than this temperature zone.

<Cooling-Warming Process>

The cooling-warming process is a process to carry out a heat treatment on the precursor (the superconducting precursor) as the periodic structure body that does not develop the bifurcation phenomenon to warm the precursor up to a temperature exceeding the bifurcation temperature after cooling the precursor up to a temperature lower than the bifurcation temperature until the warmed precursor (the superconducting precursor) exhibits an electrical resistance value of 0Ω or less, where the bifurcation phenomenon is a phenomenon in which, when the cooling resistance temperature characteristic of the periodic structure body in the cooling process of continuous heat cycles to raise temperature after cooling the periodic structure body is compared with the warming resistance temperature characteristic of the periodic structure body in the warming process, the warming resistance temperature characteristic bifurcates from the cooling resistance temperature characteristic to exhibit a high electrical resistance value at a common temperature, and the bifurcation temperature is a temperature at which the cooling resistance temperature characteristic and the warming resistance temperature characteristic bifurcate each other in the bifurcation phenomenon.

Since the electrical resistance value of 0Ω or less obtained in the cooling-warming process is maintained after warming, the properties as the superconductor are given to the periodic structure body in the cooling-warming process.

Although the cooling-warming process is carried out as a process to give the properties as the superconductor to the periodic structure body to make the periodic structure body that no longer developed the bifurcation phenomenon by the pretreatment process as the superconducting precursor, when the properties once disappears from the periodic structure body to which the properties as the superconductor are given, this process can also be carried out again as a superconductivity recovery process to recover the properties.

In other words, the periodic structure body may lose the properties as the superconductor by the application of external energy. However, even in this case, if the properties as the superconducting precursor is maintained in the periodic structure body, the properties as the superconductor once lost can be recovered by carrying out the cooling-warming process directly without going through the pretreatment process.

When it is not sure whether the periodic structure body on which the cooling-warming process is to be carried out develops the bifurcation phenomenon or not, it can be confirmed by carrying out a heat treatment similar to that in the pretreatment process on any other periodic structure body not subjected to the pretreatment process to detect the bifurcation temperature, and then using the detected bifurcation temperature as an operating temperature in the heat treatment to carry out the pretreatment process on the periodic structure body on which the cooling-warming process is to be carried out.

Further, there is a need to measure the electrical resistance value of the superconducting precursor to carry out the cooling-warming process. As the measuring method, for example, there is a method of measuring an electrical resistance value for current using a known four-terminal method or the like while adopting the current application conditions adopted in the pretreatment process.

The cooling temperature in the cooling process is not particularly limited as long as it is a temperature lower than the bifurcation temperature, but it is preferred to be a temperature of 2 K or less from the perspective of giving the properties as the superconductor to the periodic structure body with a small number of cycles. Note that the lower limit of the cooling temperature is about 10 mK.

Further, the warming temperature in the warming process is not particularly limited as long as it is a temperature exceeding the bifurcation temperature, but it is preferred to be a temperature of 300 K or more from the perspective of giving the properties as the superconductor to the periodic structure body with a small number of cycles. Note that the upper limit of the warming temperature is about 400 K.

As equipment to carry out the cooling-warming process, the same equipment as the equipment to carry out the pretreatment process can be used, and a known refrigerant Dewar or refrigerator can be used, for example.

Note that the lower speed limit of the cooling process and the warming process is not particularly limited, but it is about 0.01 K/min from the perspective of performing the heat treatment efficiently.

Further, in the cooling-warming process, the bifurcation temperature confirmed in the pretreatment process is different between heat treatment cycles of cooling and warming, and in the case of a wide temperature zone, cooling is performed at a temperature lower than this temperature zone and warming is performed at a temperature higher than this temperature zone.

Note that, when the pretreatment process and the cooling-warming process are not continuous processes and a person who carries out the cooling-warming process is unsure about the bifurcation temperature confirmed in the pretreatment process upon carrying out the cooling-warming process, the person can prepare any other sample having the same structure as the periodic structure body on which the cooling-warming process is to be carried out to perform the same heat treatment as that in the pretreatment process on this sample to confirm the bifurcation temperature.

### EXAMPLES

### Example 1

A phononic material according to Example 1 was produced as follows.

First, using a CVD system (PD-270STL made by Samco Inc.), a silicon oxide layer was formed with a thickness of 1 μm on a silicon wafer substrate (made by Miyoshi LLC; a diameter of 76.0 mm, an orientation of (100)±1°, P-type, mirror-finished surface, backside etching finish, and particles of 0.3 μm or more, whose number is ten or less).

Next, using sputtering equipment (M12-0130 made by Science Plus Co., Ltd.), a niobium layer was formed with a thickness of 150 nm on the silicon oxide layer.

Next, after forming an i-line lithography resist layer on the niobium layer using a resist coater (SK-60BW-AVP made by Dainippon Screen Mfg. Co., Ltd.), i-line lithography using a mask having a mask pattern in which holes having the same structure as a target periodic structure body were pierced was performed by i-line lithography equipment (NSR-2205i12D made by Nikon Tec Co., Ltd.) to process the resist layer into a resist pattern with the mask pattern transferred.

Next, etching processing was performed on the niobium layer through the resist pattern by a reactive ion etching system (RIE-10NR made by Samco Inc.) using SF₆ as a reaction gas to form, as a periodic structure body having the periodic structure, the niobium layer having a structure in which regions (structures) having cylindrical through holes of the same shape are regularly and periodically disposed.

Here, the state of the niobium layer on the silicon wafer substrate is illustrated in FIG. 4. Note that FIG. 4 is an explanatory drawing illustrating a state of the niobium layer as viewed from the top.

As illustrated in FIG. 4, a niobium layer 32 has such a structure that through holes 33 (a group indicated by black circles in the figure) are pieced in the thickness direction.

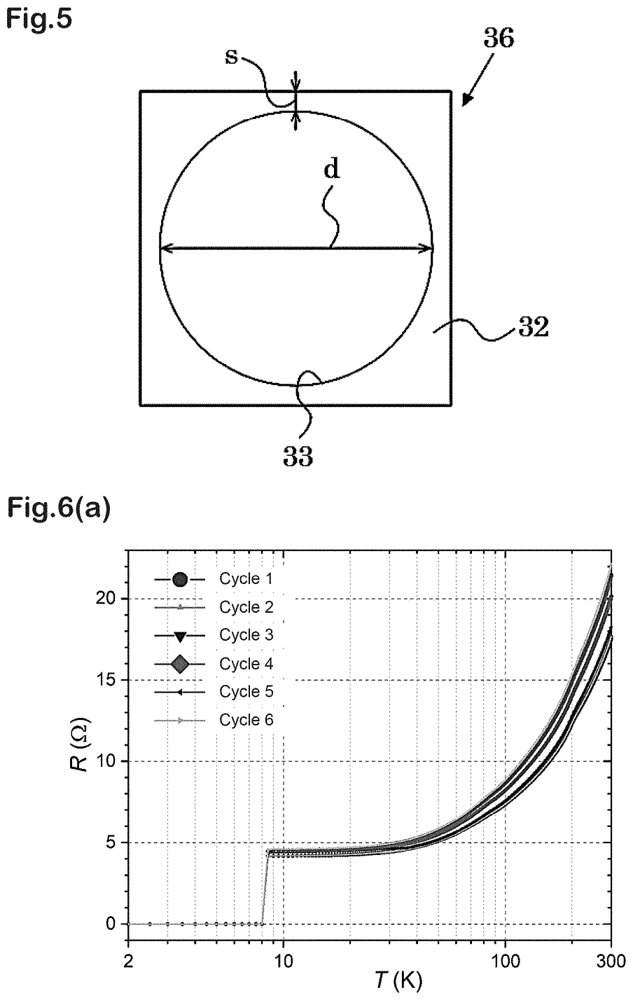

Further, in more detail, the niobium layer 32 has a structure in which 350 rectangular block regions 36 each of which is illustrated in FIG. 5 are formed. Note that FIG. 5 is an explanatory drawing illustrating each of the rectangular block regions when the niobium layer is viewed from above.

In the rectangular block region 36, a through hole 33 with a diameter d of 19.7 μm is pierced at the center.

Further, distance s between the outer circumference of the through hole 33 and the closest perimeter of the rectangular block region 36 is set to 150 nm. In other words, the niobium layer 32 as the periodic structure body has a structure in which the through holes 33 as structures are regularly and periodically disposed at intervals of 300 nm.

Further, a crystal structure when a portion in which the through holes 33 of the niobium layer 32 are formed is viewed as a phononic crystal is a square lattice, and the lattice constant is 20 μm. Note that the square lattice means such a structure that the through holes 33 are arranged on the niobium layer 32 in a square lattice shape from the top view, and the lattice constant means a distance between the center of one unit lattice and the center of any other adjacent unit lattice when each of the rectangular block regions 36 is a unit lattice.

The structure of the periodic structure body illustrated in FIG. 4 is formed based on the mask shape settings.

Next, the silicon wafer substrate in this state was cut to have the niobium layer in the center.

Next, using dry etching equipment (memsstar SVR-vHF made by Canon Inc.), HF gas is brought into contact with the silicon oxide layer under the niobium layer through the through holes to perform dry etching processing to partially remove the silicon oxide layer.

Here, sections of the silicon oxide layer located under the sections of the niobium layer 32 in which no through hole 33 is formed in FIG. 4 remain after the dry etching processing to play a role in supporting the niobium layer 32 while making sections under the sections with the through holes 33 formed into a hollow state.

Thus, the sample body of Example 1 was produced.

Next, a pretreatment process and a cooling-warming process to be described below were carried out on the sample body of Example 1, and a measurement test of the electrical resistance of a phononic material according to Example 1 obtained by these processes was performed.

First, a four-terminal resistance measuring device (P102 made by Quantum Design Japan, Inc.) was connected to the sample body of Example 1 to measure the electrical resistance of the phononic material according to Example 1.

Specifically, terminals I+, I−, V+, V− of the four-terminal resistance measuring device were connected respectively to terminals J₁, J₅, J₂, J₄ in FIG. 4 to measure the electrical resistance of the periodic structure body by reading the potential difference between the terminals J₂ and J₄ while applying current between the terminals J₁ and J₅.

Here, the application of the current between the terminals J₁ and J₅ is to restrict the current paths of current flowing through the periodic structure body in the same direction in order to supply electrons spatially uniformly into the constituent between the structures.

Next, the sample body of Example 1 was put in a physical property measuring device (PPMS made by Quantum Design Japan, Inc.), the magnitude of the magnetic field in the physical property measuring device was so set that a magnetic flux density penetrating the sample body vertically became 10 μT or less, and the pretreatment process and the cooling-warming process, in which a cooling-warming heat treatment was one cycle, were carried out under an atmosphere of helium gas of about 200 Pa to produce the phononic material according to Example 1.

As a method of measuring the electrical resistance inside the physical property measuring device in more detail, the physical property measuring device was set to “AC DRIVE MODE” and “STANDARD CALIBRATION MODE” was selected to make the measurement.

More specifically, a square wave that reverses positive and negative in a cycle of 8.33 Hz was applied between the terminals J₁ and J₅ in FIG. 4 25 times at each temperature at which the electrical resistance measurement was made, and voltage generated between the terminals J₂ and J₄ for the square wave current last applied was read to determine the electrical resistance of the periodic structure body. The application of the square wave current that reverses positive and negative in this way can minimize the output voltage offset error. Note that the amplitude of the applied square wave current is always ±10 μA during the pretreatment process and the cooling-warming process.

The details of the pretreatment process and the cooling-warming process are illustrated in Table 1 below. Note that “Fixed Point” in the table indicates that the electrical resistance was measured after each set temperature was stabilized, and “Sweep” indicates that the electrical resistance was measured while sweeping the temperature up to a target temperature set as a target.

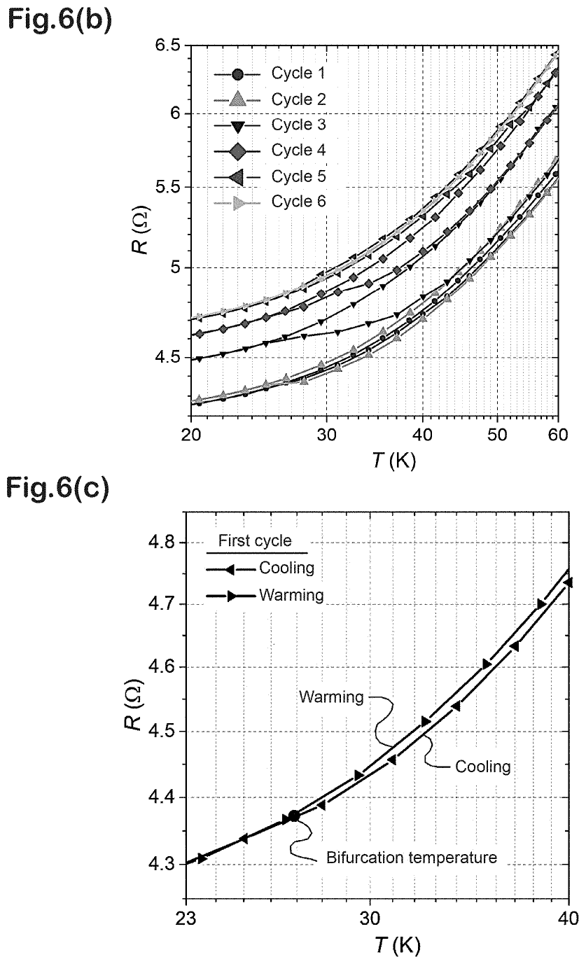

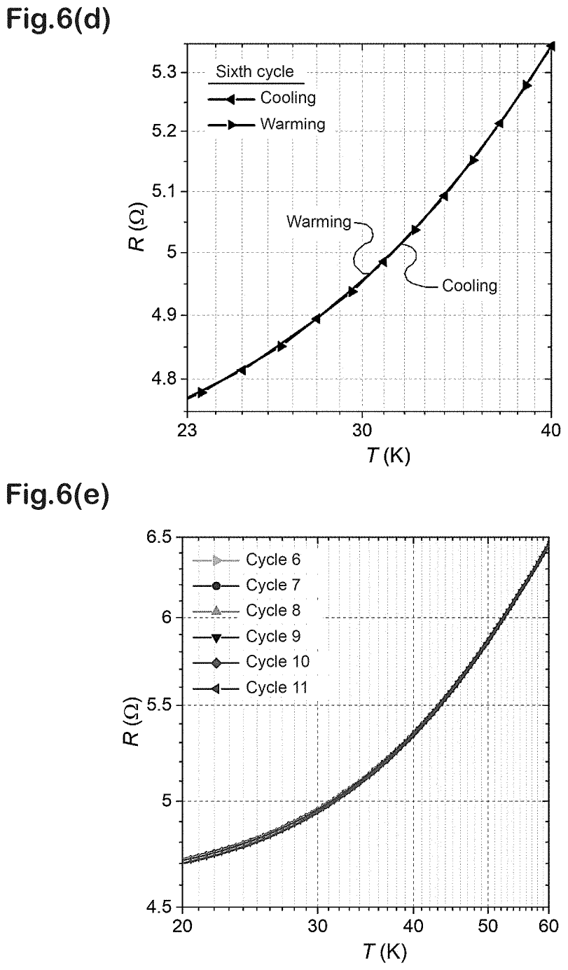

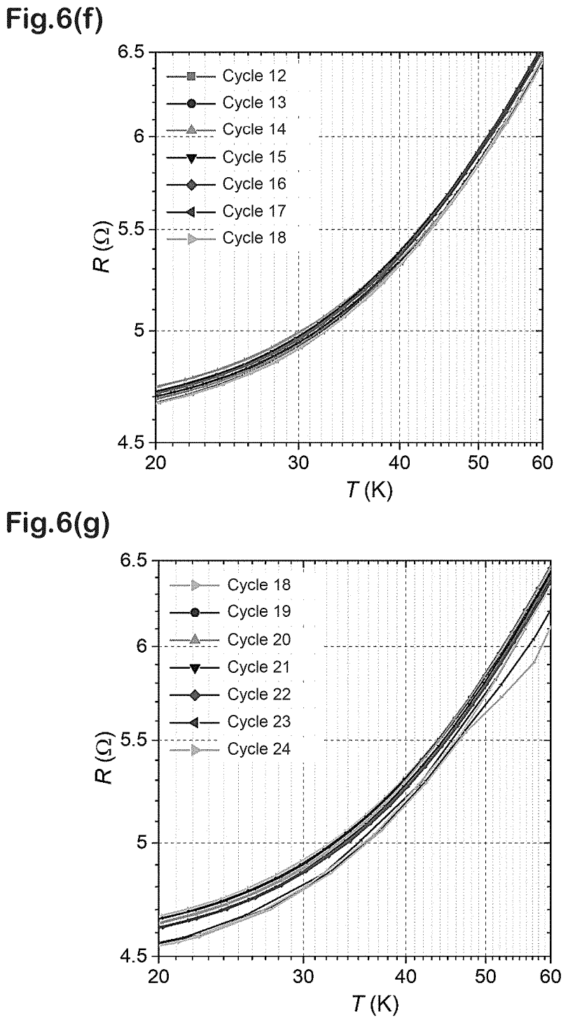

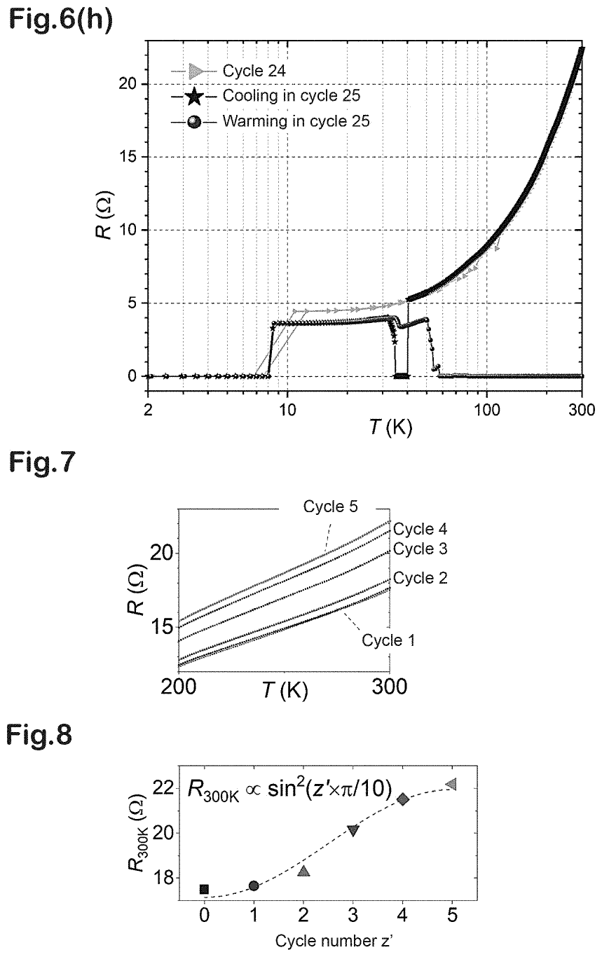

Further, the status of carrying out the pretreatment process and the cooling-warming process on the phononic material according to Example 1 and the transition status of electrical resistance values are illustrated in FIG. 6(a) to FIG. 6(h). Note that FIG. 6(a) is a graph for describing the status of carrying out the pretreatment process on the phononic material according to Example 1 and the transition status of electrical resistance values, FIG. 6(b) is a partially enlarged graph in which a range of 20 K to 60 K in FIG. 6(a) is enlarged, FIG. 6(c) is a partially enlarged graph in the first cycle, FIG. 6(d) is a partially enlarged graph in the sixth cycle, and FIG. 6(e) to FIG. 6(h) are graphs (1) to (4) illustrating the status of carrying out the cooling-warming process on the phononic material according to Example 1 and the transition status of electrical resistance values.

TABLE 1

| | | Starting | | |
|---|---|---|---|---|
| | | Temperature~ | Cooling/ | Timing of |
| | | Target | Warming | Electrical |
| Cycle | | Temperature | Speed | Resistance |
| Number | Process Name | (K) | (K/min) | Measurement |
| 1-5 | Pretreatment | 300-60 | 1.00 | Sweep |
| | Process | 60-2 | 0.50 | Fixed Point |
| | | 2-60 | 0.50 | Fixed Point |
| | | 60-300 | 1.00 | Sweep |

Disappearance of Bifurcation Phenomenon

| | | | | |
|---|---|---|---|---|
| 6-11 | Cooling/Warming | 300-60 | 1.00 | Sweep |
| | Process | 60-2 | 0.50 | Fixed Point |
| | | 2-60 | 0.50 | Fixed Point |
| | | 60-300 | 1.00 | Sweep |
| 12-13 | Cooling/Warming | 300-2 | 1.00 | Sweep |
| | Process | 2-300 | 1.00 | Sweep |
| 14-21 | Cooling/Warming | 300-2 | 2.00 | Sweep |
| | Process | 2-300 | 2.00 | Sweep |
| 22 | Cooling/Warming | 300-2 | 2.00 | Sweep |
| | Process | 2-230 | 2.00 | Sweep |
| | | 230-300 | 5.00 | Sweep |
| 23-24 | Cooling/Warming | 300-2 | 5.00 | Sweep |
| | Process | 2-300 | 5.00 | Sweep |
| 25 | Cooling/Warming | 300-50 | 1.00 | Sweep |
| | Process | 50-25 | 0.25 | Fixed Point |
| | | 25-2 | 0.50 | Sweep |
| | | 2-25 | 0.50 | Sweep |
| | | 25-50 | 0.25 | Fixed Point |
| | | 50-300 | 1.00 | Sweep |

Superconductivity

As illustrated in FIG. 6(a) to FIG. 6(d), in the heat treatment (the pretreatment process) of the first to fifth cycles, the bifurcation phenomenon in which the warming resistance temperature characteristic bifurcates from the cooling resistance temperature characteristic to exhibit a high electrical resistance value at a common temperature was confirmed, and the bifurcation temperature was confirmed in a temperature range of 25 K to 27 K. When the temperature rose by 10 K, the bifurcation phenomenon is observed significantly as an increase in the electrical resistance value of the warming resistance temperature characteristic by 20 mΩ or more at the common temperature. On the other hand, in the heat treatment of the sixth cycle, the warming resistance temperature characteristic transitioned to trace the cooling resistance temperature characteristic, and the cooling resistance temperature characteristic and the warming resistance temperature characteristic matched with each other. In other words, the bifurcation phenomenon disappeared by the heat treatment from the first cycle to the fifth cycle.

As illustrated in FIG. 7, characteristic changes of the periodic structure body in the heat treatment (the pretreatment process) from the first cycle to the fifth cycle can be confirmed as a significant resistance rise at 300 K. Note that FIG. 7 is a graph illustrating characteristic changes of the periodic structure body in the heat treatment (the pretreatment process) from the first cycle to the fifth cycle. Note that only the warming resistance temperature characteristic is illustrated for the heat treatment from the second cycle to the fifth cycle.

Further, a graph in which the cycle number z′ is plotted on the horizontal axis and the 300 K resistance value R_{300K} is plotted on the vertical axis for the periodic structure body in the heat treatment from the first cycle to the fifth cycle is illustrated in FIG. 8. Note that R_{300K} of z′=0 in FIG. 8 is the electrical resistance value (17.5Ω) at 300 K immediately before carrying out the heat treatment in the first cycle.

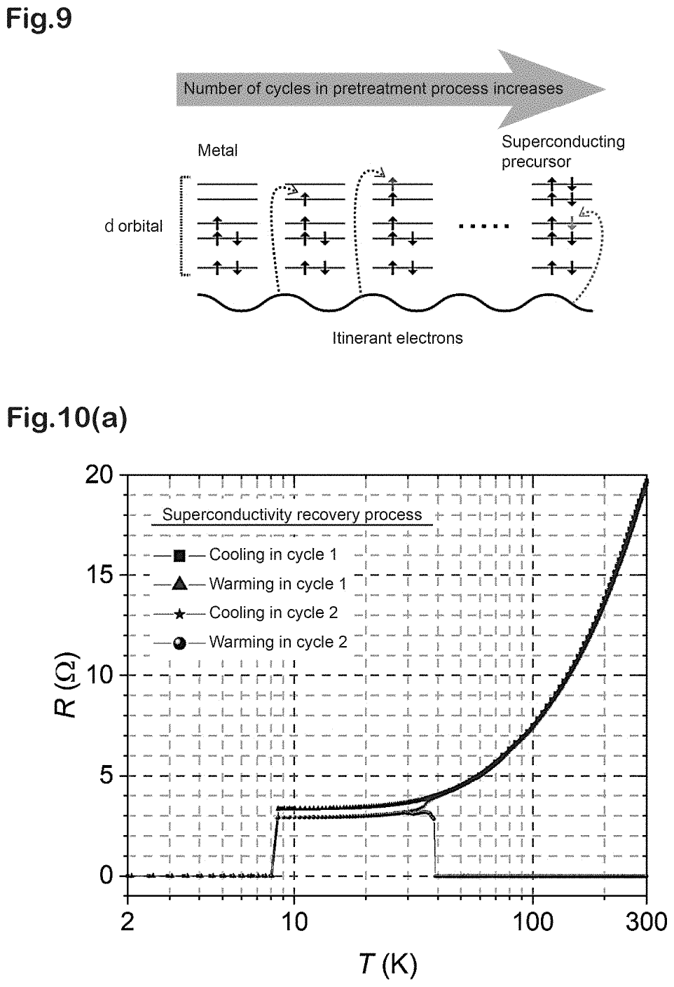

As illustrated in FIG. 8, R_{300K} is proportional to sin²(z′×π/10). This matches perfectly with the results inferred from the Friedel sum rule, and indicates that the superconducting precursor, in which electrons were localized and d orbitals were completely occupied through the pretreatment process, was formed. A transition state of the periodic structure body to the superconducting precursor in the pretreatment process is schematically illustrated in FIG. 9.

From the above, it is considered that the periodic structure body in the sample body of Example 1 became the ideal superconducting precursor through the pretreatment process.

Next, as illustrated in FIG. 6(e) to FIG. 6(h), in the heat treatment (the cooling-warming process) after the sixth cycle, such a situation that the resistance temperature characteristics move up and down as a whole each time the heat treatment is repeated was confirmed, though the bifurcation phenomenon was not observed. During this time, it is considered that the power storage states of respective tunnel junctions that construct the superconducting precursor are being well balanced to most stabilize the energy of the entire periodic structure body.

Then, as illustrated in FIG. 6(h), it was confirmed that the electrical resistance value once became zero (0Ω) at a temperature near 40 K during the cooling process of the cooling-warming process as the 25-th cycle of heat treatment, the electrical resistance value started to fall toward zero at a temperature near 50 K and became a zero resistance at a temperature near 60 K (superconducting transition) during the subsequent warming process of the cooling-warming process as the 25-th cycle of heat treatment, and after that, the zero resistance state was maintained even when the temperature was raised up to a temperature of 300 K. Since the superconducting transition temperature of niobium used as the constituent is about 9.2 K, the zero resistance was obtained at a temperature greatly exceeding the superconducting transition temperature.

From the above, the phononic material according to Example 1 was produced. Note that it was confirmed that the same properties as those of the phononic material according to Example 1 emerged in seven samples that were produced under the same production conditions.

### Example 2

When the electrical resistance value of the phononic material according to Example 1 was measured 54 days later, an electrical resistance value of 20Ω was confirmed. From the value, it is considered that the phononic material according to Example 1 returned to the metallic state. As a result of investigation using another sample produced under the same production conditions, it is assumed that a superconducting energy gap (2×Δ) of the phononic material according to Example 1 at 300 K is 1.6 eV, and that the superconducting state was destroyed by light in a visible range (wavelength <777 nm). When the superconducting state needs to be maintained, there is a need to store the phononic material according to Example 1 in a dark place.

Therefore, the phononic material according to Example 1 from which the properties as the superconductor were lost was put in the physical property measuring device to produce a phononic material according to Example 2 by carrying out the cooling-warming process (superconductivity recovery process) in the same way as when the properties as the superconductor were given to the sample body according to Example 1.

In other words, the magnitude of the magnetic field in the physical property measuring device was so set that the magnetic flux density penetrating the sample body vertically was 10 μT or less under an atmosphere of helium gas of about 200 Pa. Further, the amplitude of a square wave current applied was always ±10 μA

The details of the superconductivity recovery process are illustrated in Table 2 below.

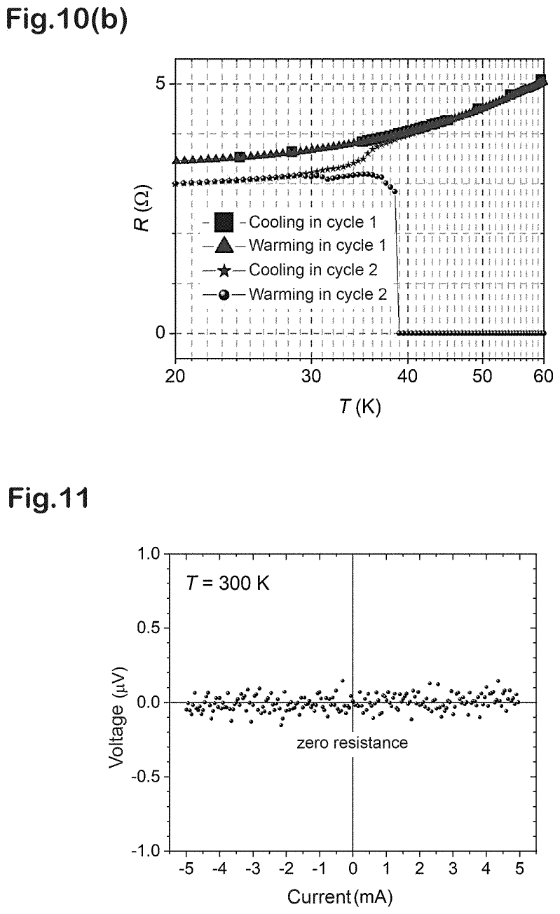

Further, the status of carrying out the superconductivity recovery process on the phononic material according to Example 2 and the transition status of electrical resistance values are illustrated in FIG. 10(a) and FIG. 10(b). Note that FIG. 10(a) is a graph illustrating the status of carrying out the superconductivity recovery process on the phononic material according to Example 2 and the transition status of electrical resistance values, and FIG. 10(b) is a partially enlarged graph in which a range of 20 K to 60 K in FIG. 10(a) is enlarged.

TABLE 2

| | | Starting | | |
|---|---|---|---|---|
| | | Temperature~ | Cooling/ | Timing of |
| | | Target | Warming | Electrical |
| Cycle | | Temperature | Speed | Resistance |
| Number | Process Name | (K) | (K/min) | Measurement |
| 1 | Superconductivity | 300-45 | 5.00 | Sweep |
| | recovery process | 45-35 | 0.50 | Sweep |
| | | 35-10 | 5.00 | Sweep |
| | | 10-2 | 0.50 | Sweep |
| | | 2-55 | 0.50 | Sweep |
| | | 55-75 | 0.10 | Sweep |
| | | 75-300 | 1.00 | Sweep |
| 2 | Superconductivity | 300-60 | 2.00 | Sweep |
| | recovery process | 60-20 | 0.50 | Fixed Point |
| | | 20-2 | 0.50 | Sweep |
| | | 2-20 | 0.50 | Sweep |
| | | 20-60 | 0.50 | Fixed Point |
| | | 60-300 | 1.00 | Sweep |

Superconductivity

As illustrated in FIG. 10(a), it can be confirmed that the electrical resistance value at 300 K immediately before carrying the first cycle is returned to 20Ω that suggests the metallic state. Further, as illustrated in FIG. 10(b), the warming resistance temperature characteristic transitioned to trace the cooling resistance temperature characteristic in the first cycle, and the cooling resistance temperature characteristic and the warming resistance temperature characteristic matched with each other. In other words, it was confirmed that the properties as the superconducting precursor was maintained though the properties as the superconductor were lost. Further, as illustrated in FIG. 10(b), the resistance temperature characteristic deviated from the resistance temperature characteristic in the first cycle at a temperature near 40 K in the cooling process of the second cycle. Then, in the warming process of the second cycle, it was confirmed that it became the zero resistance at a temperature near 40 K (superconducting transition), and after that, the zero resistance state was maintained even when the temperature was raised up to a temperature of 300 K.

Thus, even if the periodic structure body to which the properties as the superconductor was given once lost the properties as the superconductor, the periodic structure body can acquire the properties as the superconductor again by going through a small number of cycles of the superconductivity recovery process.

Next, a voltage-current characteristic measurement was made by applying a square wave current between the terminals J₁ and J₅ in FIG. 4 at 300 K while mounting the phononic material according to Example 2 on the physical property measuring device to measure voltage generated between the terminals J₂ and J₄. The results of the voltage-current characteristic measurement made on the phononic material according to Example 2 are illustrated in FIG. 11.

As illustrated in FIG. 11, voltage output in a current value range of ±5 mA falls within measurement limits of the physical property measuring device in the current value range, that is, it can be confirmed that the zero resistance is realized.

Note that the voltage-current characteristic measurement was made by setting the physical property measuring device to “DC DRIVE MODE.” In other words, a square wave current that does not reverse positive and negative was applied to the periodic structure body ten times in a cycle of 8.33 Hz for each amplitude that represents the applied current value, and the average of voltage values measured in the last two times was read to obtain the voltage-current characteristic measurement result. The reason why the applied square wave current was made not to reverse positive and negative was because a possibility that output voltage-current characteristics would exhibit origin asymmetric characteristics depending on the polarity of the applied square wave current was considered.

The measurement method using the square wave current is a powerful method for reducing the problem of a thermoelectromotive force generated in the periodic structure body, but any current exceeding the current value range off 5 mA cannot be applied.

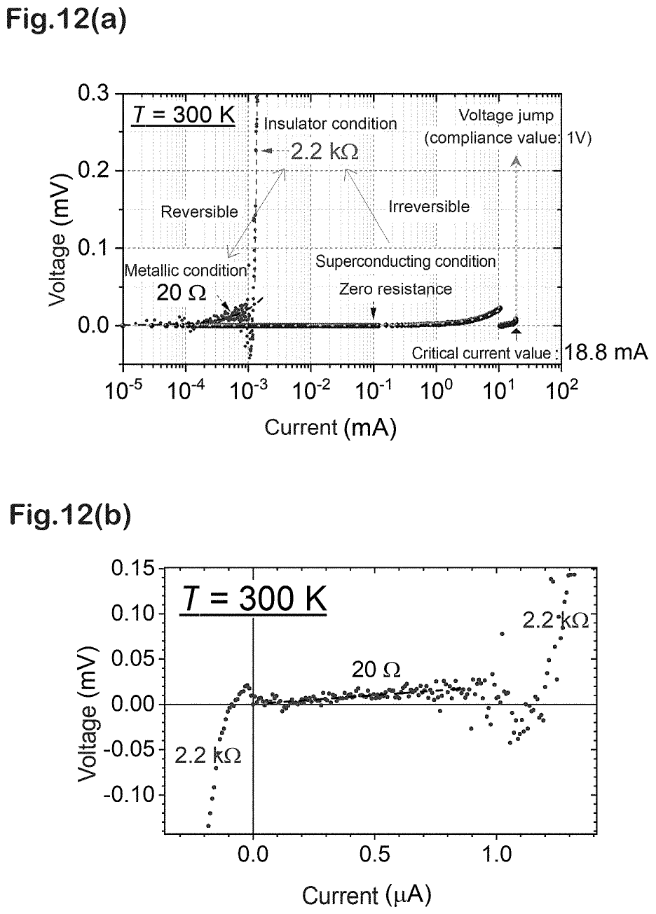

Therefore, in order to measure a critical current value of the phononic material according to Example 2, the voltage-current characteristic measurement was made by applying a direct current between the terminals J₁ and J₅ in FIG. 4 under the temperature condition of 300 K while mounting the phononic material according to Example 2 on the physical property measuring device immediately after going through the superconductivity recovery process to measure voltage generated between the terminals J₂ and J₄. Note that the measurement was carried out by connecting a source/measure unit (B2911A made by Keysight Technologies Inc.) to the physical property measuring device. The results of the voltage-current characteristic measurement when the direct current was applied to the phononic material according to Example 2 are illustrated in FIG. 12(a).

As illustrated in FIG. 12(a), when the direct current was increased from the initial value of 0 mA, a thermoelectromotive force once began to occur near 2 mA but settled into the zero resistance again near 10 mA, and finally at 18.8 mA, the voltage reached 1V as a compliance value set in the source/measure unit. In other words, the critical current value of the phononic material according to Example 2 was 18.8 mA.

Further, the results of voltage-current characteristic measurement subsequently using the source/measure unit when the direct current was applied to the phononic material according to Example 2 after applying a current exceeding the critical current value are illustrated in FIG. 12(b).

As illustrated in FIG. 12(b), it can be confirmed that the properties as the superconductor disappear by applying, to the phononic material, a current equal to or more than the critical current value.

In other words, the resistance values exhibited 20Ω metallic properties during current values of 0 μA to +1 μA, but voltage-current characteristics exhibiting insulator properties to reach a resistance value of 2.2 kΩ when the current value was less than 0 μA and exceeded 1 μA were obtained, and no zero resistance could not be confirmed anywhere, resulting in the fact that the properties as the superconductor were lost.

However, the voltage-current characteristics are not symmetric with respect to the origin, and this is unusual. The periodic structure body is an insulator for negative current, and is in a mixed state of the metal and the insulator for positive current applied to investigate the critical current value. It can be considered that some of the electrons completely occupying d orbitals were forcibly blown away by applying a large current exceeding the critical current value to the periodic structure body. In other words, it is considered that holes are overfilled in the periodic structure body having the properties as the superconductor.

In the meantime, the relationships of respective conditions, i.e., the critical current value (18.8 mA), the superconducting energy gap (Δ=0.8 eV, 2Δ=1.6 eV), the electrical resistance value (20Ω) in the metallic state at 300 K illustrated in FIG. 10(a) and FIG. 12(b), and the temperature (300 K) at which the critical current value was measured satisfy the Ambegaokar-Baratoff relational expression.

In other words, the periodic structure body that acquired the properties as the superconductor is the same intrinsic Josephson junction as the high-temperature superconductor typified by YBCO or BSCCO, which supports the consideration that it is a collection of Josephson tunnel junctions regularly disposed through the Mott-insulating parts and the conducting parts.

### Example 3

A phononic material according to Example 3 was produced as follows.

A method of producing a sample body of Example 3 is the same as that of Example 1. While carrying out the pretreatment process and the cooling-warming process on this sample body of Example 3 in the same manner as those carried out on the sample body of Example 1, an electrical resistance measurement test of a phononic material according to Example 3 obtained by these processes was performed to produce the phononic material according to Example 3.

In other words, the magnitude of the magnetic field in the physical property measuring device was such that the magnetic flux density penetrating the sample body vertically was 10 μT or less under an atmosphere of helium gas of about 200 Pa, “AC DRIVE MODE” and “STANDARD CALIBRATION MODE” were selected for the physical property measuring device, and the pretreatment process and the cooling-warming process were carried out while performing the electrical resistance measurement test by applying a square wave current that reverses positive and negative with an amplitude of ±10 μA.

The details of the pretreatment process and the cooling-warming process are illustrated in Table 3-1 and Table 3-2 below.

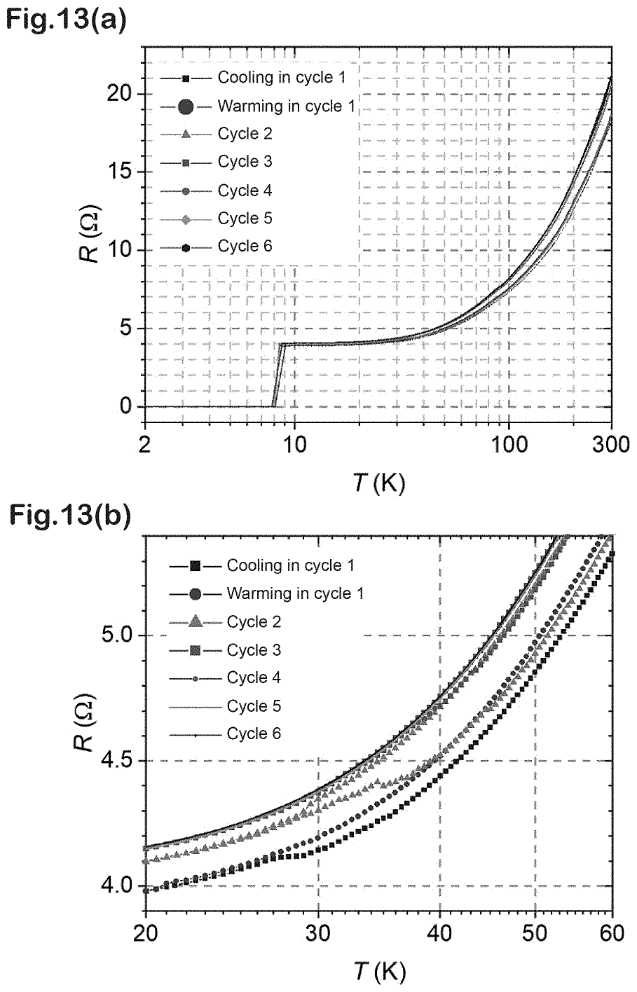

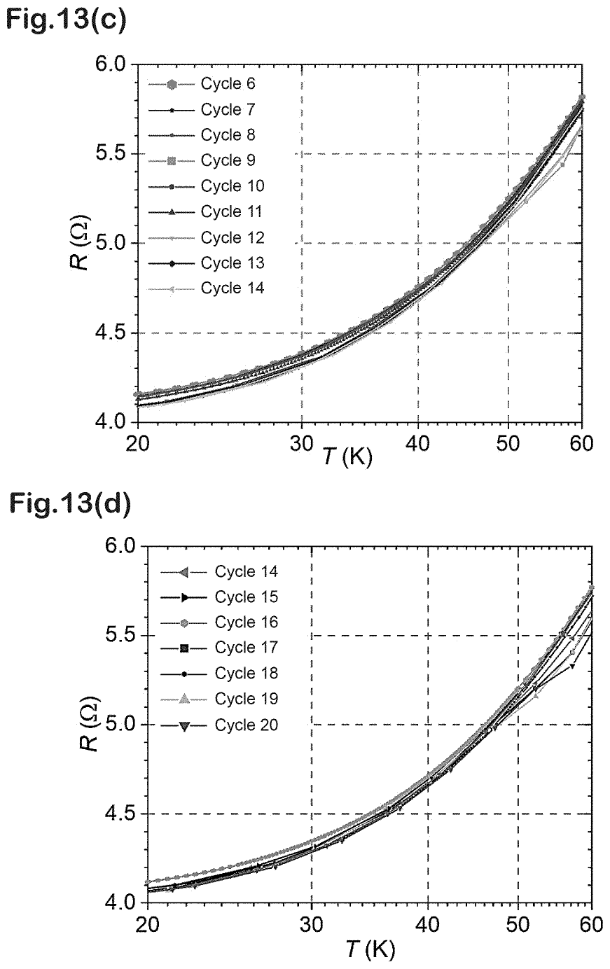

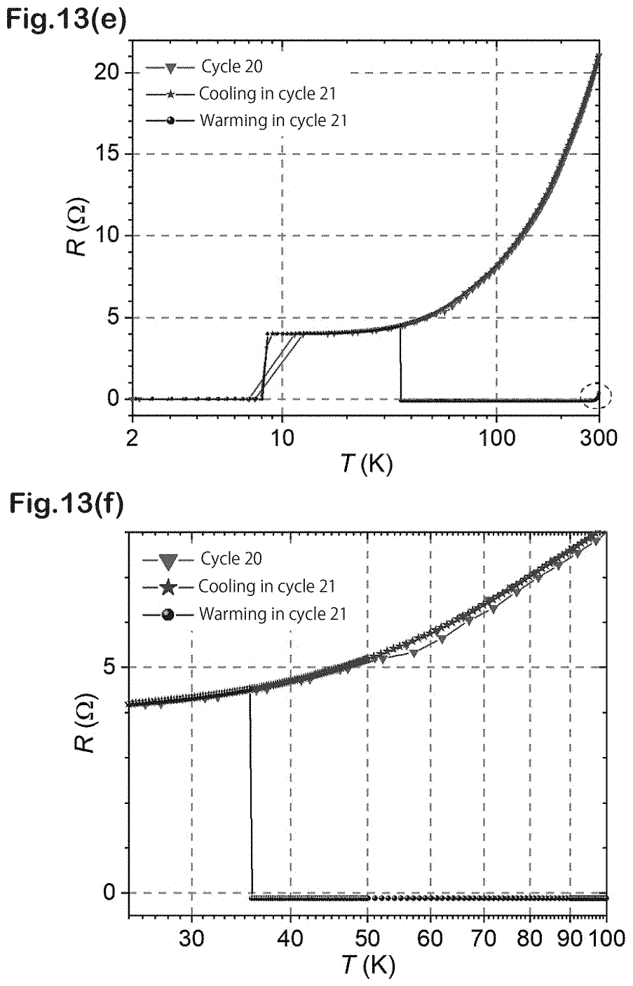

Further, the status of carrying out the pretreatment process and the cooling-warming process on the phononic material according to Example 3 and the transition status of electrical resistance values are illustrated in FIG. 13(a) to FIG. 13(f). Note that FIG. 13(a) is a graph for describing the status of carrying out the pretreatment process and the cooling-warming process on the phononic material according to Example 3 and the transition status of electrical resistance values, FIG. 13(b) is a partially enlarged graph in which a range of 20 K to 60 K in FIG. 13(a) is enlarged, FIG. 13(c) to FIG. 13(e) are graphs (1) to (3) illustrating the status of carrying out the cooling-warming process on the phononic material according to Example 3 and the transition status of electrical resistance values, and FIG. 13(f) is a partially enlarged graph in which a range of 25 K to 100 K in FIG. 13(e) is enlarged.

TABLE 3-1

| | | Starting | | |
|---|---|---|---|---|
| | | Temperature~ | Cooling/ | Timing of |
| | | Target | Warming | Electrical |
| Cycle | Process | Temperature | Speed | Resistance |
| Number | Name | (K) | (K/min) | Measurement |
| 1-3 | Pretreatment | 300-60 | 1.00 | Sweep |
| | Process | 60-2 | 0.50 | Fixed Point |
| | | 2-60 | 0.50 | Fixed Point |
| | | 60-300 | 1.00 | Sweep |

Disappearance of Bifurcation Phenomenon

| | | | | |
|---|---|---|---|---|
| 4 | Cooling/Warming | 300-60 | 1.00 | Sweep |
| | Process | 60-2 | 0.50 | Fixed Point |
| | | 2-60 | 0.50 | Fixed Point |
| | | 60-300 | 1.00 | Sweep |
| 5 | Cooling/Warming | 300-50 | 1.00 | Sweep |
| | Process | 50-25 | 0.25 | Fixed Point |
| | | 25-2 | 0.50 | Sweep |
| | | 2-25 | 0.50 | Sweep |
| | | 25-50 | 0.25 | Fixed Point |
| | | 50-300 | 1.00 | Sweep |
| 6 | Cooling/Warming | 300-2 | 1.00 | Sweep |
| | Process | 2-300 | 1.00 | Sweep |
| 7-8 | Cooling/Warming | 300-2 | 2.00 | Sweep |
| | Process | 2-300 | 2.00 | Sweep |
| 9 | Cooling/Warming | 300-2 | 5.00 | Sweep |
| | Process | 2-300 | 5.00 | Sweep |
| 10 | Cooling/Warming | 300-2 | 5.00 | Sweep |
| | Process | 2-25 | 0.50 | Sweep |
| | | 25-50 | 0.25 | Fixed Point |
| | | 50-300 | 1.00 | Sweep |
| 11 | Cooling/Warming | 300-50 | 1.00 | Sweep |
| | Process | 50-25 | 0.25 | Fixed Point |
| | | 25-2 | 0.50 | Sweep |
| | | 2-25 | 0.50 | Sweep |
| | | 25-50 | 0.25 | Fixed Point |
| | | 50-300 | 1.00 | Sweep |
| 12 | Cooling/Warming | 300-2 | 5.00 | Sweep |
| | Process | 2-300 | 5.00 | Sweep |

TABLE 3-2

| | | Starting | | |
|---|---|---|---|---|
| | | Temperature~ | Cooling/ | Timing of |
| | | Target | Warming | Electrical |
| Cycle | Process | Temperature | Speed | Resistance |
| Number | Name | (K) | (K/min) | Measurement |
| 13 | Cooling/Warming | 300-2 | 5.00 | Sweep |
| | Process | 2-20 | 0.50 | Sweep |
| | | 20-60 | 0.25 | Fixed Point |
| | | 60-300 | 1.00 | Sweep |
| 14-15 | Cooling/Warming | 300-2 | 5.00 | Sweep |
| | Process | 2-300 | 5.00 | Sweep |
| 16 | Cooling/Warming | 300-50 | 1.00 | Sweep |
| | Process | 50-25 | 0.25 | Fixed Point |
| | | 25-2 | 0.50 | Sweep |
| | | 2-25 | 0.50 | Sweep |
| | | 25-50 | 0.25 | Fixed Point |
| | | 50-300 | 1.00 | Sweep |
| 17 | Cooling/Warming | 300-2 | 5.00 | Sweep |
| | Process | 2-300 | 5.00 | Sweep |
| 18 | Cooling/Warming | 300-2 | 5.00 | Sweep |
| | Process | 2-25 | 0.50 | Sweep |
| | | 25-50 | 0.25 | Sweep |
| | | 50-90 | 1.00 | Sweep |
| | | 90-110 | 0.25 | Fixed Point |
| | | 110-300 | 1.00 | Sweep |
| 19-20 | Cooling/Warming | 300-2 | 5.00 | Sweep |
| | Process | 2-300 | 5.00 | Sweep |
| 21 | Cooling/Warming | 300-50 | 1.00 | Sweep |
| | Process | 50-25 | 0.25 | Fixed point |
| | | 25-2 | 0.50 | Sweep |
| | | 2-25 | 0.50 | Sweep |
| | | 25-50 | 0.25 | Fixed point |
| | | 50-90 | 1.00 | Sweep |
| | | 90-110 | 0.25 | Sweep |
| | | 110-300 | 1.00 | Sweep |

Superconductivity

As illustrated in FIG. 13(a) and FIG. 13(b), in the heat treatment (the pretreatment process) of the first to third cycles, the bifurcation phenomenon in which the warming resistance temperature characteristic bifurcates from the cooling resistance temperature characteristic to exhibit a high electrical resistance value at a common temperature was confirmed, and the bifurcation temperature was confirmed in a temperature range of 21 K to 32 K. When the temperature rose by 10 K, the bifurcation phenomenon was observed significantly as an increase in the electrical resistance value of the warming resistance temperature characteristic by 20 mΩ or more at the common temperature. On the other hand, in the heat treatment of the fourth cycle, the warming resistance temperature characteristic transitioned to trace the cooling resistance temperature characteristic, and the cooling resistance temperature characteristic and the warming resistance temperature characteristic matched with each other. In other words, the bifurcation phenomenon disappeared by the heat treatment from the first cycle to the third cycle.

Characteristic changes of the periodic structure body in the heat treatment (the pretreatment process) from the first cycle to the third cycle can be confirmed as a significant resistance rise at 300 K.

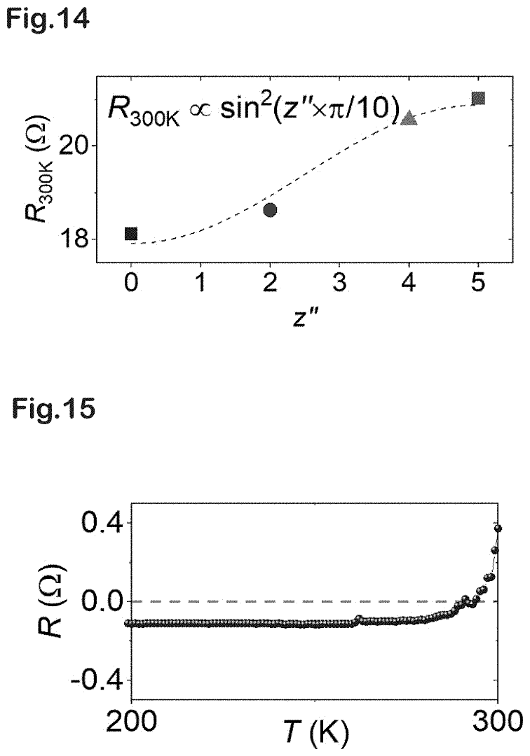

Further, a graph for the periodic structure body in the heat treatment of the first to third cycles, in which the 300 K resistance value R_{300K} is plotted on the vertical axis and z″ is plotted on the horizontal axis in such a manner that R_{300K} immediately before the heat treatment of the first cycle is carried out corresponds to z″=0, R_{300K} in the first cycle corresponds to z″=2, R_{300K} in the second cycle corresponds to z″=4, and R_{300K} in the third cycle corresponds to z″=5, respectively, is illustrated in FIG. 14. Note that R_{300K} at z″=0 in FIG. 14 is an electrical resistance value (18.1Ω) at 300 K immediately before the first cycle is carried out.

As illustrated in FIG. 14, R_{300K} is proportional to sin²(z′×π/10), and this matches perfectly with the results inferred from the Friedel sum rule. It should be considered that the d orbital was completely occupied by causing additional two electrons to occupy the d orbital in the heat treatment of the first cycle, causing further additional two electrons to occupy the d orbital in the heat treatment of the next second cycle, and causing additional one electron to occupy the d orbital in the heat treatment of the last third cycle.

In other words, the results illustrated in FIG. 14 indicate that the superconducting precursor in which electrons in niobium were localized to occupy the d orbital completely through the pretreatment process of the constituent was formed.

From the above, it is considered that the periodic structure body in the sample body of Example 3 also became the ideal superconducting precursor through the pretreatment process like the periodic structure body in the sample body of Example 1.

As illustrated in FIG. 13(a) to FIG. 13(d), in the heat treatment (the cooling-warming process) after the fourth cycle, such a situation that the resistance temperature characteristics move up and down as a whole each time the heat treatment is repeated was confirmed, though the bifurcation phenomenon was not observed.

Then, as illustrated in FIG. 13(e) and FIG. 13(f), it was confirmed that the electrical resistance value became a negative value near zero (a negative value of less than 0Ω) at a temperature near 35 K during the warming process in the cooling-warming process as the heat treatment of the 21st cycle. As illustrated in FIG. 15, it was confirmed that the negative resistance state was maintained up to a temperature near 280 K but the resistance value slightly rose near 290 K to exhibit a positive value. Note that FIG. 15 is a graph illustrating resistance temperature characteristics of the periodic structure body in the phononic material according to Example 3.

In the cooling-warming process, the superconducting precursor produced through the pretreatment process spontaneously balanced the power storage states of respective tunnel junctions that construct the superconducting precursor to most stabilize the energy of the entire periodic structure body in order to acquire properties as the superconductor, but in the periodic structure body of the phononic material according to Example 3, it is considered that having a negative electrical resistance at a temperature up to near 280 K is the most stable state of the entire periodic structure body.

Although Example 3 was carried out as one of the reproduction tests of Example 1, it seems that the result became different from that of Example 1 due to differences in heat treatment operation timing and the like. In either case, a phononic material that stably exhibits properties as the superconductor can be produced in Example 1 and Example 3.

### DESCRIPTION OF REFERENCE NUMERALS

1, 20 phononic material
2, 22a, 22b constituent
2′, 12, 22, 22′ periodic structure body
3, 13, 23a, 23b, 23′ structure
4, 24 substrate
5, 25 spacer
26 cubic block area
32 niobium layer
33 through hole
36 rectangular block region

1. A phononic material comprising
a periodic structure body in which structures are periodically and regularly disposed in a constituent containing elements having d orbital,
wherein the periodic structure body exhibits an electrical resistance characteristic less than or equal to 0Ω and has a temperature region that exhibits the electrical resistance characteristic in a temperature range exceeding a superconducting transition temperature when the constituent has the superconducting transition temperature.

2. The phononic material according to claim 1, wherein the periodic structure body exhibits an electrical resistance characteristic of a negative value.

3. The phononic material according to claim 1, wherein the constituent contains a transition metal element.

4. The phononic material according to claim 1, wherein the periodic structure body is formed in a layer state, and the structures are through holes.

5. The phononic material according to claim 4, wherein an opening diameter of each through hole is 1 nm to 10 mm.

6. The phononic material according to claim 4, wherein an interval between adjacent two through holes is 1 nm to 0.1 mm.

7. The phononic material according to claim 4, wherein a thickness of the periodic structure body formed in the layer state is 0.1 nm to 0.01 mm.

8. A phononic material comprising
a periodic structure body in which structures are periodically and regularly disposed in a constituent containing elements having d orbital,
wherein the periodic structure body does not develop a bifurcation phenomenon as a phenomenon in which, when a cooling resistance temperature characteristic of the periodic structure body in a cooling process of continuous heat cycles to raise temperature after cooling the periodic structure body is compared with a warming resistance temperature characteristic of the periodic structure body in a warming process, the warming resistance temperature characteristic bifurcates from the cooling resistance temperature characteristic to exhibit a high electrical resistance value at a common temperature.

9. A method for producing the phononic material according to claim 8, comprising
a pretreatment process to obtain a precursor as the periodic structure body that does not develop the bifurcation phenomenon by carrying out a heat treatment to warm the periodic structure body up to a temperature exceeding a bifurcation temperature after cooling the periodic structure body up to a temperature lower than the bifurcation temperature in a state of applying a unidirectional current to the periodic structure body until the bifurcation phenomenon disappears, where the bifurcation temperature is a temperature at which the cooling resistance temperature characteristic and the warming resistance temperature characteristic bifurcate each other in the bifurcation phenomenon.

10. A method for producing the phononic material according to claim 1, comprising
a cooling-warming process to carry out a heat treatment on a precursor as the periodic structure body that does not develop a bifurcation phenomenon to warm the precursor up to a temperature exceeding a bifurcation temperature after cooling the precursor up to a temperature lower than the bifurcation temperature until the warmed precursor exhibits an electrical resistance value of 0Ω or less, where the bifurcation phenomenon is a phenomenon in which, when a cooling resistance temperature characteristic of the periodic structure body in a cooling process of continuous heat cycles to raise temperature after cooling the periodic structure body is compared with a warming resistance temperature characteristic of the periodic structure body in a warming process, the warming resistance temperature characteristic bifurcates from the cooling resistance temperature characteristic to exhibit a high electrical resistance value at a common temperature, and the bifurcation temperature is a temperature at which the cooling resistance temperature characteristic and the warming resistance temperature characteristic bifurcate each other in the bifurcation phenomenon.
